(19) United States
(12) Patent Application Publication
(10) Pub. No.: US 2022/0399202 A1
(43) Pub. Date: Dec. 15, 2022

(54) SEMICONDUCTOR DEVICE AND MANUFACTURING METHOD THEREOF

(71) Applicant: United Microelectronics Corp., Hsinchu (TW)

(72) Inventor: Jingyu Fan, Singapore (SG)

(73) Assignee: United Microelectronics Corp., Hsinchu (TW)

(21) Appl. No.: 17/368,055

(22) Filed: Jul. 6, 2021

(30) Foreign Application Priority Data
Jun. 9, 2021 (CN) 202110640870.5

(51) Int. Cl. H01L 21/02; H01L 23/532

(52) U.S. Cl. CPC H01L 21/02129; H01L 21/02131; H01L 21/02203; H01L 21/0214; H01L 23/53295

(57) ABSTRACT

Provided are a semiconductor device and a manufacturing method thereof. The semiconductor device includes a substrate, a semiconductor device structure, a doped dielectric layer and an interlayer dielectric layer. The substrate has a first surface and a second surface opposite to each other. The semiconductor device structure is disposed on the first surface. The doped dielectric layer is disposed on the second surface. The interlayer dielectric layer is disposed on the doped dielectric layer.

### CROSS-REFERENCE TO RELATED APPLICATION

This application claims the priority benefit of China application serial no. 202110640870.5, filed on Jun. 9, 2021. The entirety of the above-mentioned patent application is hereby incorporated by reference herein and made a part of this specification.

### BACKGROUND

### Technical Field

The present invention relates to a semiconductor device and a manufacturing method thereof.

### Description of Related Art

In the current specific semiconductor manufacturing process, after various device structures are formed on the front surface (or called the active surface) of the substrate, a specific manufacturing process is performed on the back surface of the substrate. For example, a chemical mechanical polishing (CMP) process may be performed on the back surface of the substrate to thin the substrate, and various circuit structures may be formed on the back surface of the substrate.

For the chemical mechanical polishing process, after the back surface of the substrate is polished, the chemical mechanical polishing chamber is cleaned. However, during the cleaning process, the metal ions, such as potassium ions, etc., in the cleaning solution used may diffuse from the back surface of the substrate to the inside of the substrate, even into various devices, thus affecting the electrical properties of the devices. In addition, in addition to the metal ions in the cleaning solution, the metal ions used in other various processes may also diffuse from the back surface of the substrate to the inside of the substrate, even into various devices.

### SUMMARY

The present invention provides a semiconductor device in which a doped dielectric layer is disposed between the back surface of a substrate and an interlayer dielectric layer disposed on the back surface.

The present invention provides a manufacturing method of a semiconductor device, wherein a doped dielectric layer is formed between the back surface of a substrate and an interlayer dielectric layer disposed on the back surface.

A semiconductor device of the present invention includes a substrate, a semiconductor device structure, a doped dielectric layer and an interlayer dielectric layer. The substrate has a first surface and a second surface opposite to each other. The semiconductor device structure is disposed on the first surface. The doped dielectric layer is disposed on the second surface. The interlayer dielectric layer is disposed on the doped dielectric layer.

In an embodiment of the semiconductor device of the present invention, the doped dielectric layer has a relatively high dielectric constant, and the interlayer dielectric layer has a relatively low dielectric constant.

In an embodiment of the semiconductor device of the present invention, the material of the doped dielectric layer includes phosphor-silicate glass (PSG), boro-silicate glass (BSG), boro-phospho-silicate glass (BPSG) or a combination thereof.

In an embodiment of the semiconductor device of the present invention, the thickness of the doped dielectric layer is between 1000 Å and 2000 Å.

In an embodiment of the semiconductor device of the present invention, the interlayer dielectric layer is a porous layer.

In an embodiment of the semiconductor device of the present invention, the material of the interlayer dielectric layer includes fluoro-silicate glass (FSG).

In an embodiment of the semiconductor device of the present invention, the thickness of the interlayer dielectric layer is at least 2500 Å.

In an embodiment of the semiconductor device of the present invention, an etching stop layer is further disposed between the second surface and the doped dielectric layer.

In an embodiment of the semiconductor device of the present invention, the material of the etching stop layer includes silicon oxynitride (SiN), silicon carbide (SiC) or a combination thereof.

In an embodiment of the semiconductor device of the present invention, the thickness of the etching stop layer is between 500 Å and 1000 Å.

A manufacturing method of a semiconductor device of the present invention includes the following steps. A substrate having a first surface and a second surface opposite to each other is provided. A semiconductor device structure is formed on the first surface. A doped dielectric layer is disposed on the second surface. An interlayer dielectric layer is formed on the doped dielectric layer.

In an embodiment of the manufacturing method of the semiconductor device of the present invention, the doped dielectric layer has a relatively high dielectric constant, and the interlayer dielectric layer has a relatively low dielectric constant.

In an embodiment of the manufacturing method of the semiconductor device of the present invention, the material of the doped dielectric layer includes phosphor-silicate glass, boro-silicate glass, boro-phospho-silicate glass or a combination thereof.

In an embodiment of the manufacturing method of the semiconductor device of the present invention, the thickness of the doped dielectric layer is between 1000 Å and 2000 Å.

In an embodiment of the manufacturing method of the semiconductor device of the present invention, the interlayer dielectric layer is a porous layer.

In an embodiment of the manufacturing method of the semiconductor device of the present invention, the material of the interlayer dielectric layer includes fluoro-silicone glass.

In an embodiment of the manufacturing method of the semiconductor device of the present invention, the thickness of the interlayer dielectric layer is at least 2500 Å.

In an embodiment of the manufacturing method of the semiconductor device of the present invention, an etching stop layer is further formed on the second surface after forming the semiconductor device structure and before forming the doped dielectric layer.

In an embodiment of the manufacturing method of the semiconductor device of the present invention, the material of the etching stop layer includes silicon oxynitride, silicon carbide or a combination thereof.

In an embodiment of the manufacturing method of the semiconductor device of the present invention, the thickness of the etching stop layer is between 500 Å and 1000 Å.

Based on the above, in the semiconductor device of present invention, a doped dielectric layer is disposed between the interlayer dielectric layer and the substrate. Therefore, during the manufacturing process, the doped dielectric layer may prevent metal ions from diffusing into the substrate, even into various devices, which may prevent the electrical properties of the devices from being affected by metal ions.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1C are schematic cross-sectional views of a manufacturing process of a semiconductor device according to an embodiment of present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

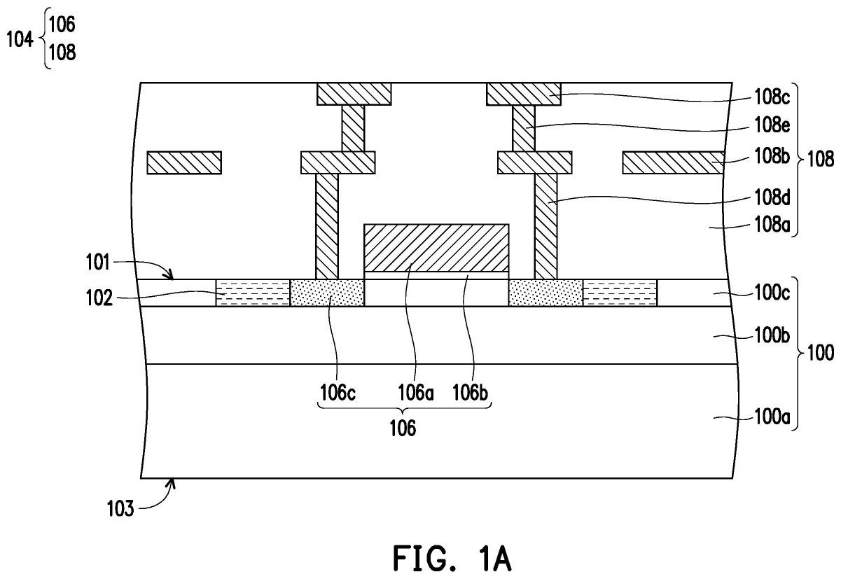

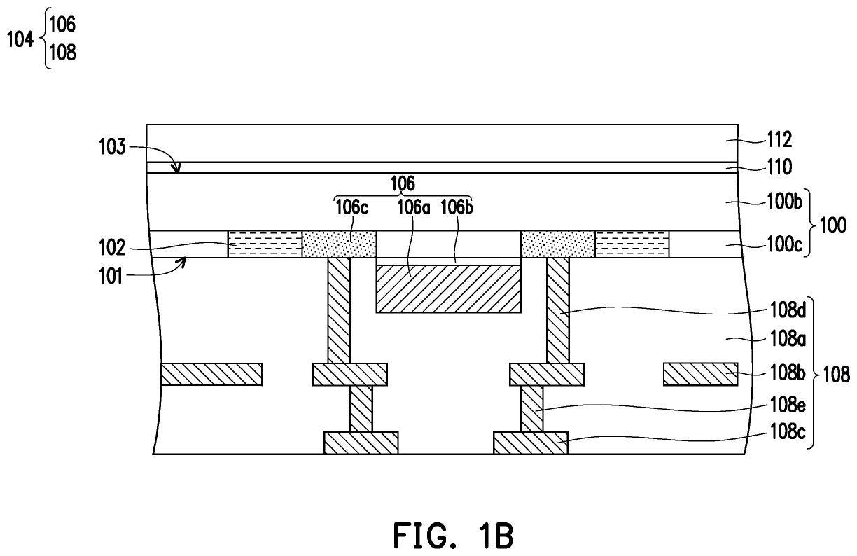

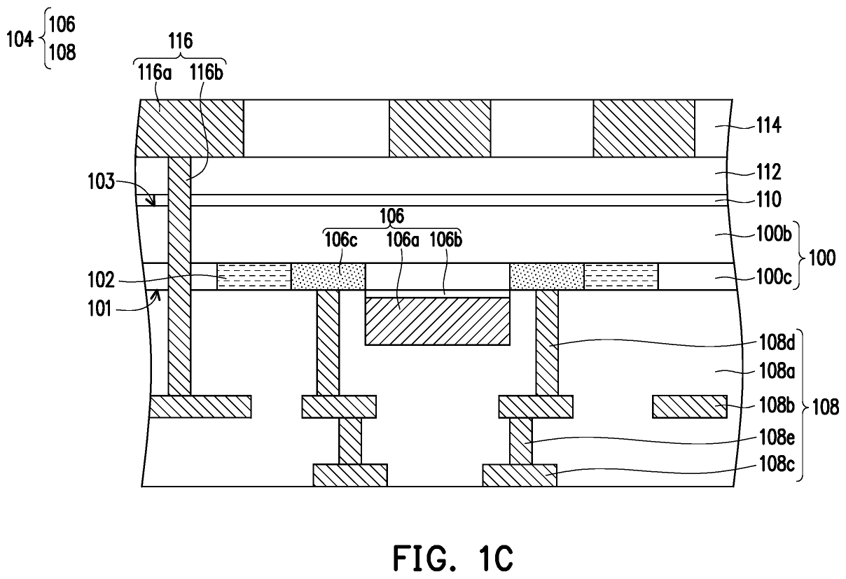

FIGS. 1A to 1C are schematic cross-sectional views of a manufacturing process of a semiconductor device according to an embodiment of present invention.

Referring to FIG. 1A, a silicon-on-insulator (SOI) substrate 100 is provided. The silicon-on-insulator substrate 100 includes a silicon base 100a and a dielectric layer 100b and a silicon layer 100c sequentially disposed on the silicon base 100a. Generally, the silicon base 100a may be doped with P-type dopants and preferably has a thickness of about 5000 Å, the dielectric layer 100b preferably has a thickness of more than about 2 μm, and the silicon layer 100c may be doped with P-type dopants and preferably has a thickness greater than about 0.5 μm. In the present embodiment, the dielectric layer 100b is, for example, a silicon oxide layer. In the present embodiment, the silicon-on-insulator substrate 100 has a first surface 101 and a second surface 103 opposite to each other. At this stage, the first surface 101 is the front surface (also called the active surface) on which the semiconductor devices are formed, i.e., the exposed top surface of the silicon layer 100c, and the second surface 103 is the back surface, i.e., the exposed bottom surface of the silicon base 100a.

Then, an isolation structure 102 is formed in the silicon layer 100c to define an active area (AA). The isolation structure 102 is, for example, a shallow trench isolation (STI) structure. In the present embodiment, the thickness of the isolation structure 102 is the same as the thickness of the silicon layer 100c, that is, the isolation structure 102 penetrates the silicon layer 100c, so that adjacent active areas may be effectively isolated. The forming method of the isolation structure 102 is well known to those skilled in the art, and will not be further described here.

Next, a semiconductor device structure 104 is formed on the first surface 101. In the present embodiment, the semiconductor device structure 104 includes a transistor device 106 formed on the active surface (the first surface 101) of the substrate 100 and an interconnect structure 108 formed on the transistor device 106, but the present invention is not limited thereto. The interconnect structure 108 is electrically connected with the transistor device 106. In the present embodiment, the transistor device 106 includes a gate 106a, a gate dielectric layer 106b and source/drain regions 106c. The gate 106a is formed on the active surface (the first surface 101), the gate dielectric layer 106b is formed between the gate 106a and the active surface, and the source/drain regions 106c are formed in the silicon layer 100c at both sides of the gate 106a. In addition, in the present embodiment, the interconnect structure 108 includes a dielectric layer 108a, a circuit layer 108b, a circuit layer 108c, contacts 108d and vias 108e. The dielectric layer 108a is formed on the first surface 101 and covers the transistor device 106. The circuit layer 108b, the circuit layer 108c, the contacts 108d and the vias 108e are formed in the dielectric layer 108a. The circuit layer 108b is electrically connected to the source/drain regions 106c of the transistor device 106 through the contacts 108d, and the circuit layer 108c is electrically connected to the circuit layer 108b through the vias 108e. Those skilled in the art may form other various semiconductor devices on the first surface 101 according to actual needs, and the present invention does not limit this.

Referring to FIG. 1B, after the transistor device 106 and the interconnect structure 108 are formed, the silicon base 100a is removed. In the present embodiment, the method for removing the silicon base 100a includes the following steps. A grinding process is performed to remove most of the silicon base 100a, and then an etching process is performed to remove the remaining silicon base 100a, but present invention is not limited thereto. At this time, the substrate 100 includes the dielectric layer 100b and the silicon layer 100c, and the back surface (the second surface 103) of the substrate 100 is the exposed surface of the dielectric layer 100b. Then, an etching stop layer 110 is optionally formed on the second surface 103. The forming method of the etching stop layer 110 is, for example, a chemical vapor deposition (CVD) process. The material of the etching stop layer 110 is, for example, silicon oxynitride, silicon carbide or a combination thereof. The thickness of the etching stop layer 110 is, for example, between 500 Å and 1000 Å.

After forming the etching stop layer 110, a doped dielectric layer 112 is formed on the etching stop layer 110. The forming method of the doped dielectric layer 112 is, for example, a chemical vapor deposition process. The material of the doped dielectric layer 112 is, for example, phosphor-silicate glass (PSG), boro-silicate glass (BSG), boro-phospho-silicate glass (BPSG) or a combination thereof, which has a dielectric constant greater than 3. The thickness of the doped dielectric layer 112 is, for example, between 1000 Å and 2000 Å. The doped dielectric layer 112 is used to block the diffusion of metal ions in the subsequent process into the substrate 100. In the present embodiment, the doped dielectric layer 112 has a characteristic of trapping metal ions, thereby making it difficult (or even impossible) for the metal ions to enter the inside of the substrate 100. When the thickness of the doped dielectric layer 112 is less than 1000 Å, the doped dielectric layer 112 may not be able to effectively block the diffusion of metal ions in the subsequent process into the inside of the substrate 100. When the thickness of the doped dielectric layer 112 is greater than 2000 Å, the doped dielectric layer 112 may block excessive metal ions, thereby affecting the electrical properties of the semiconductor device of present invention.

Referring to FIG. 1C, an interlayer dielectric layer 114 is formed on the doped dielectric layer 112. The forming method of the interlayer dielectric layer 114 is, for example, a chemical vapor deposition process. The material of the interlayer dielectric layer 114 is, for example, fluoro-silicate glass (FSG), which has a dielectric constant of 3 or less. That is, in the present embodiment, the doped dielectric layer 112 has a relatively high dielectric constant, and the interlayer dielectric layer 114 has a relatively low dielectric constant. The thickness of the interlayer dielectric layer 114 is at least 2500 Å to facilitate subsequent formation of the conductive devices. In an embodiment, the interlayer dielectric layer 114 may be a porous layer. Next, a conductive device 116 electrically connected to the interconnect structure 108 is formed in the interlayer dielectric layer 114. In the present embodiment, the conductive device 116 includes a circuit layer 116a and vias 116b, but the present invention is not limited thereto. The circuit layer 116a is formed in the interlayer dielectric layer 114. The vias 116b are connected to the circuit layer 116a and extended from the circuit layer 116a through the doped dielectric layer 112, the etching stop layer 110, the dielectric layer 100b and the silicon layer 100c into the dielectric layer 108a to be connected to the circuit layer 108b, but the present invention is not limited thereto. The forming method of conductive device 116 may include the following steps. Trenches are formed in the interlayer dielectric layer 114 and openings are formed in the doped dielectric layer 112, the etching stop layer 110, the dielectric layer 100b, the silicon layer 100c and the dielectric layer 108a. The trenches and openings are filled with a conductive material. A chemical mechanical polishing (CMP) process is performed to remove the conductive material outside the trenches and the openings.

After the chemical mechanical polishing process, the chemical mechanical polishing chamber is cleaned. During the cleaning process, the cleaning solution used contains metal ions, such as potassium ions, etc. In the present embodiment, since the doped dielectric layer 112 is formed between the interlayer dielectric layer 114 and the substrate 100 and the doped dielectric layer 112 has the characteristic of trapping metal ions, it may prevent the metal ions from diffusing into the inside of the substrate 100, even into the transistor device 106 and the interconnect structure 108. Further, in addition to the metal ions in the cleaning solution, the doped dielectric layer 112 may also prevent the metal ions used in the subsequent process from diffusing into the inside of the substrate 100, even into the transistor device 106 and the interconnect structure 108.

The following will take the structure in FIG. 1C as an example to describe the semiconductor device of the present invention.

As shown in FIG. 1C, the semiconductor device of the present invention at least includes the substrate 100, the semiconductor device structure 104, the doped dielectric layer 112 and the interlayer dielectric layer 114. The semiconductor device structure 104 is disposed on the front surface (the first surface 101) of the substrate 100, and the doped dielectric layer 112 is disposed on the back surface (the second surface 103) of the substrate 100. The interlayer dielectric layer 114 is disposed on the doped dielectric layer 112.

In the semiconductor device of the present invention, since the doped dielectric layer 112 is disposed between the interlayer dielectric layer 114 and the substrate 100 and the doped dielectric layer 112 has the characteristic of trapping metal ions, during the subsequent manufacturing process performed on the semiconductor device of the present invention, the doped dielectric layer 112 may prevent metal ions from diffusing into the substrate 100, even into various devices, thereby preventing the electrical properties of the devices from being affected by the metal ions.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a substrate having a first surface and a second surface opposite to each other;
a semiconductor device structure, disposed on the first surface;
a doped dielectric layer, disposed on the second surface; and
an interlayer dielectric layer, disposed on the doped dielectric layer.

2. The semiconductor device of claim 1, wherein the doped dielectric layer has a relatively high dielectric constant, and the interlayer dielectric layer has a relatively low dielectric constant.

3. The semiconductor device of claim 1, wherein the material of the doped dielectric layer comprises phosphor-silicate glass, boro-silicate glass, boro-phospho-silicate glass or a combination thereof.

4. The semiconductor device of claim 1, wherein the thickness of the doped dielectric layer is between 1000 Å and 2000 Å.

5. The semiconductor device of claim 1, wherein the interlayer dielectric layer is a porous layer.

6. The semiconductor device of claim 1, wherein the material of the interlayer dielectric layer comprises fluoro-silicate glass.

7. The semiconductor device of claim 1, wherein the thickness of the interlayer dielectric layer is at least 2500 Å.

8. The semiconductor device of claim 1, further comprising an etching stop layer disposed between the second surface and the doped dielectric layer.

9. The semiconductor device of claim 8, wherein the material of the etching stop layer comprises silicon oxynitride, silicon carbide or a combination thereof.

10. The semiconductor device of claim 8, wherein the thickness of the etching stop layer is between 500 Å and 1000 Å.

11. A manufacturing method of a semiconductor device, comprising:
providing a substrate having a first surface and a second surface opposite to each other;
forming a semiconductor device structure on the first surface;
forming a doped dielectric layer on the second surface; and
forming an interlayer dielectric layer on the doped dielectric layer.

12. The manufacturing method of a semiconductor device of claim 11, wherein the doped dielectric layer has a relatively high dielectric constant, and the interlayer dielectric layer has a relatively low dielectric constant.

13. The manufacturing method of a semiconductor device of claim 11, wherein the material of the doped dielectric layer comprises phosphor-silicate glass, boro-silicate glass, boro-phospho-silicate glass or a combination thereof.

14. The manufacturing method of a semiconductor device of claim 11, wherein the thickness of the doped dielectric layer is between 1000 Å and 2000 Å.

15. The manufacturing method of a semiconductor device of claim 11, wherein the interlayer dielectric layer is a porous layer.

16. The manufacturing method of a semiconductor device of claim 11, wherein the material of the interlayer dielectric layer comprises fluoro-silicone glass.

17. The manufacturing method of a semiconductor device of claim 11, wherein the thickness of the interlayer dielectric layer is at least 2500 Å.

18. The manufacturing method of a semiconductor device of claim 11, further comprising forming an etching stop layer on the second surface after forming the semiconductor device structure and before forming the doped dielectric layer.

19. The manufacturing method of a semiconductor device of claim 18, wherein the material of the etching stop layer comprises silicon oxynitride, silicon carbide or a combination thereof.

20. The manufacturing method of a semiconductor device of claim 18, wherein the thickness of the etching stop layer is between 500 Å and 1000 Å.
